(19) United States
(12) Patent Application Publication
(10) Pub. No.: US 2002/0096713 A1
(43) Pub. Date: Jul. 25, 2002

(54) Semi-conductor device

(75) Inventors: Petrus Hubertus Cornelis Magnee, Eindhoven (NL); Hendrik Gezienus Albert Huizing, Eindhoven (NL); Freerk Van Rijs, Nijmegen (NL)

Correspondence Address: Corporate Patent Counsel, U.S. Philips Corporation, 580 White Plains Road, Tarrytown, NY, 10591, US

(73) Assignee: Koninklijke Philips Electronics N.V.

(21) Appl. No.: 10/055,348

(22) Filed: Jan. 22, 2002

(30) Foreign Application Priority Data
Jan. 23, 2001 (EP) 01200233.3

(51) Int. Cl. H01L 29/76

(52) U.S. Cl. 257/341

(57) ABSTRACT

The present invention relates to semi-conductor device comprising:

a substrate;

a first semi-conducting region of a first conductive type adjacent to the substrate and provided with a first contact part arranged on the side of the device situated opposite the substrate;

a second semi-conducting region of a second, opposite conductive type, the center line of which extends in the form of a polygon, which region has a first junction to the first semi-conducting region and which is provided with a second contact part arranged on the side of the device situated opposite the substrate;

a third semi-conducting region of the same conductive type as the first semi-conducting region, the center line of which extends in the form of a polygon, which region has a first junction to the second semi-conducting region and which is provided with a third contact part arranged on the side of the device situated opposite the substrate.

The invention relates to the field of power transistors based on semiconductors. A particular application of such transistors is in portable devices, such as mobile telephones, which depend on batteries for their energy. It is important for such devices that energy is used economically. An important parameter for transistors is the Power Added Efficiency (PAE). This PAE is the ratio of the output power minus the input power and the power of the direct current, and is important because a lower PAE means that more current is consumed from the battery for a given output power and therefore means a shorter battery life.

The present invention relates to a semi-conductor device comprising:

a substrate;

a first semi-conducting region of a first conductive type adjacent to the substrate and provided with a first contact part arranged on the side of the device situated opposite the substrate;

a second semi-conducting region of a second, opposite conductive type, the centre line of which extends in the form of a polygon, which region has a first junction to the first semi-conducting region and which is provided with a second contact part arranged on the side of the device situated opposite the substrate;

a third semi-conducting region of the same conductive type as the first semi-conducting region, the centre line of which extends in the form of a polygon, which region has a first junction to the second semi-conducting region and which is provided with a third contact part arranged on the side of the device situated opposite the substrate.

In a preferred embodiment this device is embodied as transistor, wherein:

the first region is a collector of the N type;

the second region is a base of the P type;

the third region is an emitter of the N type.

The transistor can further be embodied such that all contact parts can be connected to the side of the device away from the substrate and that the polygon is a hexagon. It is also preferable to use as much space as possible on a microchip. For this reason a hexagon is developed. Filling a surface with hexagons is possible without losing surface area between adjacent transistors and simultaneously it is the hexagon that comes closest to the circumference-surface ratio of a circle. In comparison, a circle or square would also be able to fill an area but these shapes have a worse circumference-surface ratio.

A transistor with such a hexagonal form has the advantage that the collector surface area is small per emitter length, whereby relatively little energy is lost per supplied power quantity since the quantity of supplied power depends on the length of the emitter. The collector-substrate capacity is also small in this form of transistor. Since this capacity is an important factor of energy loss, a small capacity is advantageous.

It is recommended that the collector contact is connected to the collector via a buried N-region with low resistance which extends both laterally and vertically, wherein the lateral part is enclosed by the collector.

It is also advantageous for the base to be arranged vertically relative to the collector.

An embodiment is further provided wherein the base contact makes contact with the base via a fourth and a fifth region consisting of semi-conducting material and wherein the emitter is arranged vertically relative to the base, and which base contact makes contact with the other side of the base relative to the collector.

It is recommended that the emitter be electrically insulated from the semiconductor regions which connect the base to the base contact.

In this design this electric insulation makes it possible to place the base and the emitter close together and to provide the base with contacts along two sides of the emitter, which has the advantage that the small base has a better electrical connection than if this was only possible along one side.

In the first region, and completely enclosed hereby, a sixth region, the centre line of which extends in the form of a polygon, can be arranged substantially vertically under the second region.

An embodiment of the invention provides the option of a plurality of assemblies of second and third regions lying mutually adjacently are arranged on one or more first regions in a pattern wherein the space between the second and third regions is minimized.

It is further advantageous for one or more buried semi-conductor N-regions for connecting one or more collectors to one or more collector contacts to be mutually connected.

The hexagonal transistor is designed as small as possible in order to obtain an optimal ratio between negative effects such as the collector-substrate capacity and the positive effect of the power amplification in order to obtain the highest possible PAE per surface area of the transistor. An example of an optimal minimum size with the so-called double polysilicon process is 65 μm emitter length along the edges of a hexagon. This aspect is described in greater detail in the detailed description hereinbelow. However, if a greater power amplification is desired than a hexagon of the optimum format can provide, a plurality of optimal hexagonal transistors can then be combined in order to achieve the desired power.

Further according to the present invention the collectors are not arranged separately but more than one emitter is combined with a continuous collector region. The supplied power is proportional to the emitter length. More emitter length per collector is therefore advantageous. In view of the material properties, the ratio cannot become better than in the case of an optimal hexagon.

If in such an embodiment a number of buried collector contacts are also mutually connected, the advantage then becomes even greater. The reason for this is the difference between the contribution to the collector-substrate capacity from an edge of the collector contacts and of a part of the bottom surface area thereof. The edge contribution is 1.0 fF per μm and the bottom contribution is 0.1 fF per square μm. These values are very specific for the process used in these embodiments, the values may differ for other processes.

In the case of mutually abutting transistors it is hereby advantageous to exchange a small quantity of the edge of the collector-substrate for a small amount of surface area. For a further description hereof reference is made to the detailed description below.

A further object of the invention is to provide a method for forming a semiconductor device, comprising:

a substrate;

a first semi-conducting region of a first conductive type adjacent to the substrate and provided with a first contact part arranged on the side of the device situated opposite the substrate;

a second semi-conducting region of a second, opposite conductive type, the centre line of which extends in the form of a polygon, which region has a first junction to the first semi-conducting region and which is provided with a second contact part arranged on the side of the device situated opposite the substrate;

a third semi-conducting region of the same conductive type as the first semi-conducting region, the centre line of which extends in the form of a polygon, which region has a first junction to the second semi-conducting region and which is provided with a third contact part arranged on the side of the device situated opposite the substrate.

An advantage hereof is that all the contacts are at one end of the device. This means that power amplification by this device is possible without interfering with other devices on the same microprocessor.

An embodiment of this method for producing a semi-conductor device, comprises the following steps:

doping a lateral N-region in the substrate,

applying to the substrate an epitaxial N-layer which forms the first region,

applying an oxide layer over the epitaxial layer,

applying a vertical N-region in the first region integrally with the lateral N-region in the substrate,

applying a fourth region as a transition region between the base and the base contact,

etching an emitter opening in the P-region,

diffusing a fifth region from the fourth region,

implanting the second region and a sixth region, the centre line of which extends in the form of a polygon,

forming insulation material against the fourth and fifth regions in order to insulate said regions from the third region,

forming the third region by means of deposition and doping thereof with N-type dopant,

diffusing the emitter from the doped polysilicon.

The method described in the above is a brief description of the double polysilicon process using which the embodiments in the detailed description can be produced.

Further advantages, features and details of the present invention will become apparent upon reading of the following description of a preferred embodiment, with reference to the associated figures, wherein:

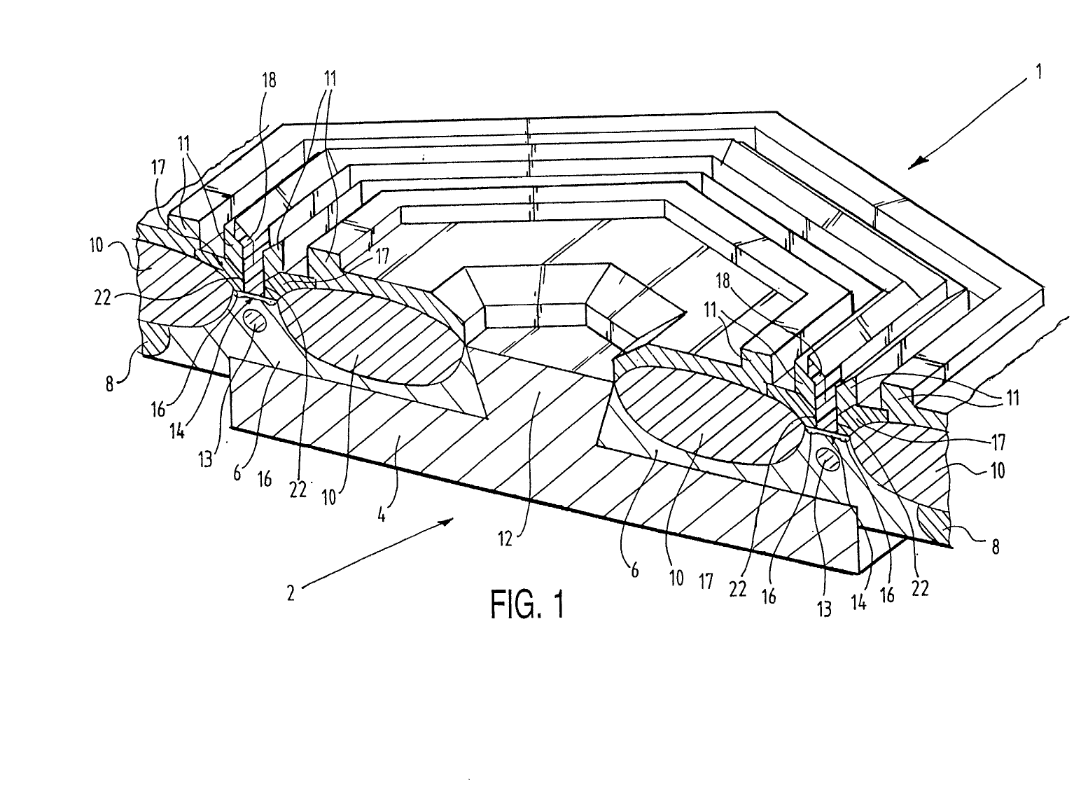

FIG. 1 is a partly broken away perspective representation of a preferred embodiment of a device according to the invention.

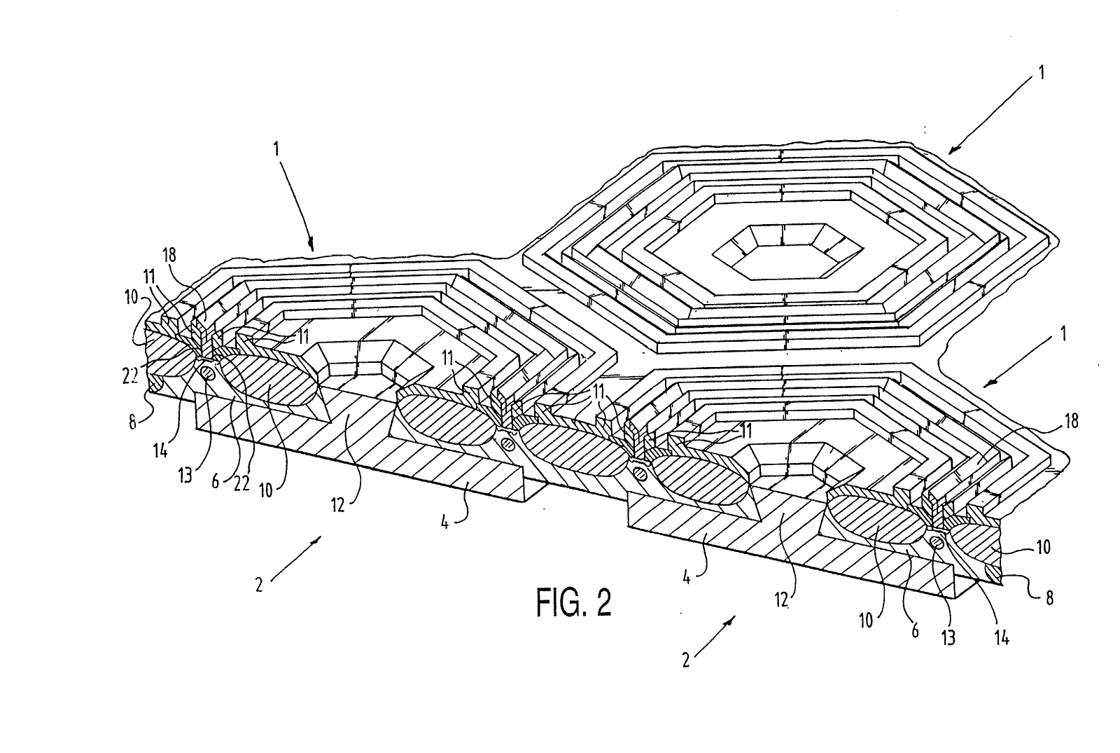

FIG. 2 is a partly broken away perspective representation of an assembly of three devices of the embodiment of FIG. 1.

FIG. 1 shows components of an embodiment of the transistor. The embodiment is constructed on a substrate 2 of lowly doped P-type material. Situated herein is a buried N-region 4, which serves as a conductive region with a low resistance between the collector and a collector contact (not shown). Above this is situated an N-type layer 6 which serves as collector. The device has a substantially hexagonal form. As insulation for the rectangular form there is provided a substantially hexagonal boundary 8 there around consisting of P-type material. This insulates and encloses the N-type collector. An interrupted insulation layer silicon oxide (SiO₂) 10 is arranged on top of the collector, wherein the interruptions serve for connection of contacts of the base, the emitter and the collector to be further described. A further insulation layer 11 is arranged to insulate the base contacts 17 from the emitter 18 and is arranged during the production process in the form of a complete insulation layer in which openings are later created. On the upper side of the region serving as conductor to the collector contact can be seen a vertical part 12 hereof which extends vertically upward through the collector from the horizontal part 4 of the collector contact. On either side of the cross-section of FIG. 1 a selective collector 13 is implanted in a local elevation of the collector. Immediately above this, but not against it, is situated the base 14. This base is of P-type material. On either side of this base are situated small P-regions 16 which form the connection between the base and base contact parts 17. Situated on top of the base is the emitter 18 consisting of N-type material and on either side of this emitter are situated contact parts 17 of base 14 consisting of P-type material. These base contacts and the emitter are insulated from each other by means of insulation material 22. The base, emitter and collector are connected to other parts of a circuit of which they form part by means of for instance metal contacts (not shown).

These transistors are suitable for use as power amplifiers. They are specifically suitable for power amplifiers in high-frequency ranges such as for instance between 1 and 2 gigahertz.

When a signal is amplified in a transistor a part of the power is always lost, i.e. more power goes into the transistor than comes out as effective signal. A significant parameter for these high frequency applications is the Power Added Efficiency (PAE). This PAE is equal to the high frequency output power minus the high frequence input power divided by the supplied power. This PAE is particularly important for wireless applications since it has a direct influence on the battery life: more DC power required for a given output power means that more current from the battery is used. In practice the PAE is mainly reduced by parasitic, such as the collector-substrate capacity and the collector and substrate resistance. Of main significance for this invention is the collector-substrate capacity.

Recent insights teach that not only does the loss-causing output capacity contribute toward a decrease in the PAE but also that, in the extreme case the said resistance is zero, there is still a decrease in the PAE as collector-substrate capacity increases.

The collector-substrate capacity is a junction capacity of the buried N-region for the collector connection to the P-substrate. As this capacity is proportional to the surface area of the buried layer, it is advantageous to keep this surface area as small as possible. It is further the case for virtually all bipolar IC processes that a significant part of the collector-substrate capacity consists of edge contributions. With the NPN transistor in a hexagonal structure two advantages are obtained:

1) The contribution from the bottom of the collector-substrate capacity is reduced by the smaller surface area.

2) The edge contribution is minimized in that a hexagon gives an optimal compromise between the lowest possible edge length and the best possible area filling (can be almost completely filled with regular hexagons).

In transistors with the above described structure a bottom contribution amounts to 0.1 fF/μm² and an edge contribution to 1.0 fF/μm. It can further be seen clearly that the vertical part 12 of the collector contact is situated in the centre of a hexagonally embodied transistor. The collector has a hexagonal form and emitter 18 and base 14 run substantially round the hexagon. A transistor with this form has a proportionally low collector-substrate capacity and thereby a proportionally large PAE. A hexagonal transistor has a surface area of about 350 micrometers and a circumference of 70 micrometers. This produces a collector-substrate capacity of 105 fF.

In the case that a larger power transistor is required, several hexagons can be used adjacently of each other (FIG. 2).

FIG. 2 shows three hexagonal transistors. However, in the case a number of hexagons are each positioned mutually abutting with one of their sides, the collectors can be formed integrally along these sides. This has the advantage that the edges become shorter and the drawback that the surface area becomes larger. However, since the edge capacity which disappears is many times greater than the surface area capacity which takes its place, this is advantageous, certainly in the case where a plurality of transistors are placed together. A calculation will demonstrate this. Take the same 10 hexagons as above. If in this case the collector contacts are connected to each other, this gives a surface area of 5100 μm² and an edge length of 330 μm, and this produces a total collector-substrate capacity of 840 fF.

The same number of hexagons without continuous collector contact gives a collector-substrate capacity of a total of 10 times 105, which is 1050 fF, this being 25% more than if the contacts are continuous.

1. Semi-conductor device comprising:
a substrate;
a first semi-conducting region of a first conductive type adjacent to the substrate and provided with a first contact part arranged on the side of the device situated opposite the substrate;
a second semi-conducting region of a second, opposite conductive type, the centre line of which extends in the form of a polygon, which region has a first junction to the first semi-conducting region and which is provided with a second contact part arranged on the side of the device situated opposite the substrate;
a third semi-conducting region of the same conductive type as the first semi-conducting region, the centre line of which extends in the form of a polygon, which region has a first junction to the second semi-conducting region and which is provided with a third contact part arranged on the side of the device situated opposite the substrate.

2. Device as claimed in claim 1, wherein:
the first region is a collector of the N type;
the second region is a base of the P type;
the third region is an emitter of the N type.

3. Device as claimed in claim 1 and/or 2, wherein all contact parts can be connected to the side of the device remote from the substrate.

4. Device as claimed in claim 1, wherein the polygon is a hexagon.

5. Device as claimed in one or more of the foregoing claims, wherein the collector contact is connected to the collector via a buried N-region with low resistance which extends both laterally and vertically, wherein the lateral part is enclosed by the collector.

6. Device as claimed in one or more of the foregoing claims, wherein the base is arranged vertically relative to the collector.

7. Device as claimed in one or more of the foregoing claims, wherein the base contact makes contact with the base via a fourth and a fifth region consisting of semi-conducting material.

8. Device as claimed in one or more of the foregoing claims, wherein the emitter is arranged vertically relative to the base and which makes contact with the other side of the base relative to the collector.

9. Device as claimed in one or more of the foregoing claims, wherein the emitter is electrically insulated from the semi-conductor regions which connect the base to the base contact.

10. Device as claimed in one or more of the foregoing claims, wherein in the first region, and completely enclosed hereby, a sixth region, the centre line of which extends in the form of a polygon, is arranged substantially vertically under the second region.

11. Device as claimed in one or more of the foregoing claims, wherein a plurality of assemblies of second and third regions lying mutually adjacently are arranged on one or more first regions in a pattern wherein the space between the second and third regions is minimized.

12. Device as claimed in claim 10, wherein one or more buried semi-conductor N-regions for connecting one or more collectors to one or more collector contacts are mutually connected.

13. Method for forming a semi-conductor device, comprising:
a substrate;
a first semi-conducting region of a first conductive type adjacent to the substrate and provided with a first contact part arranged on the side of the device situated opposite the substrate;
a second semi-conducting region of a second, opposit conductive type, the centre line of which extends in the form of a polygon, which region has a first junction to the first semi-conducting region and which is provided with a second contact part arranged on the side of the device situated opposite the substrate;
a third semi-conducting region of the same conductive type as the first semi-conducting region, the centre line of which extends in the form of a polygon, which region has a first junction to the second semi-conducting region and which is provided with a third contact part arranged on the side of the device situated opposite the substrate.

14. Method for producing a semi-conductor device as claimed in claim 11, comprising the following steps of:
doping a lateral N-region in the substrate,
applying to the substrate an epitaxial N-layer which forms the first region,
applying an oxide layer over the epitaxial layer,
applying a vertical N-region in the first region integrally with the lateral N-region in the substrate,
applying a fourth region as a transition region between the base and the base contact,
etching an emitter opening in the P-region,
diffusing a fifth region from the fourth region,
implanting the second region and a sixth region, the centre line of which extends in the form of a polygon,
forming insulation material against the fourth and fifth regions in order to insulate said regions from the third region,
forming the third region by means of deposition and doping thereof with N-type dopant,
diffusing the emitter from the doped polysilicon.
